(19) United States
(12) Patent Application Publication
(10) Pub. No.: US 2022/0230856 A1
(43) Pub. Date: Jul. 21, 2022

(54) PLASMA PROCESSING SYSTEM AND PLASMA PROCESSING METHOD

(71) Applicant: Tokyo Electron Limited, Tokyo (JP)

(72) Inventors: Ichiro SONE, Miyagi (JP); Hideaki NAGASAKI, Miyagi (JP)

(73) Assignee: Tokyo Electron Limited, Tokyo (JP)

(21) Appl. No.: 17/579,643

(22) Filed: Jan. 20, 2022

(30) Foreign Application Priority Data
Jan. 20, 2021 (JP) 2021-007413

(51) Int. Cl. H01J 37/32; H01J 37/18

(52) U.S. Cl. CPC H01J 37/32862; H01J 37/32935; H01J 37/18; H01J 37/3244; H01J 37/32642

(57) ABSTRACT

According to an aspect of the present disclosure, there is provided a plasma processing system for performing plasma processing on a substrate, the plasma processing system including: a chamber to which a consumable member is attached inside; a vacuum transfer chamber connected to the chamber; a transfer device provided in the vacuum transfer chamber and configured to transfer the consumable member between the chamber and the transfer device; a measuring instrument provided outside the chamber in the plasma processing system and configured to detect a state of the consumable member; and a controller configured to control each element of the plasma processing system.

### CROSS-REFERENCE TO RELATED APPLICATION

This application claims priority to Japanese Patent Application No. 2021-007413, filed on Jan. 20, 2021, the entire contents of which are incorporated herein by reference.

### TECHNICAL FIELD

The present disclosure relates to a plasma processing system and a plasma processing method.

### BACKGROUND

A plasma processing apparatus for performing plasma processing by placing a substrate on a stage provided inside a processing chamber is known. In a plasma processing apparatus, a consumable member that is gradually consumed by repeating plasma processing is present (for example, refer to Japanese Patent Application Publication No. 2018-10992). Examples of the consumable member include a focus ring (edge ring) provided around the substrate on an upper surface of the stage. Since the edge ring is reduced due to exposure to plasma, it is necessary to periodically replace the edge ring.

### SUMMARY

The present disclosure provides a technique capable of detecting a state of a consumable member.

According to an aspect of the present disclosure, there is provided a plasma processing system for performing plasma processing on a substrate, the plasma processing system including: a chamber to which a consumable member is attached inside; a vacuum transfer chamber connected to the chamber; a transfer device provided in the vacuum transfer chamber and configured to transfer the consumable member between the chamber and the transfer device; a measuring instrument, provided outside the chamber in the plasma processing system and configured to detect a state of the consumable member; and a controller configured to control each element of the plasma processing system.

According to the present disclosure, it is possible to detect the state of the consumable member.

### BRIEF DESCRIPTION OF THE DRAWINGS

FIG. 1 is a view illustrating an example of a plasma processing system of a first embodiment.

FIG. 2 is a diagram illustrating an example of a hardware configuration of the plasma processing system of the first embodiment.

FIG. 3 is a view illustrating an example of a thickness detection sensor.

FIG. 4 is a vertical sectional view illustrating an example of a plasma processing apparatus of an embodiment.

FIG. 5 is a view for describing a raising/lowering pin for raising or lowering an edge ring.

FIG. 6 is a view for describing a heat transfer gas supplied to a rear surface of the edge ring.

FIG. 7 is a view for describing a direct-current (DC) power source for applying a DC voltage to the edge ring.

FIG. 8 is a view for describing a multi-zone heater.

FIG. 9 is a flowchart illustrating an example of a transfer method of a first embodiment.

FIG. 10 is a flowchart illustrating another example of the transfer method of the first embodiment.

FIG. 11 is a view illustrating an example of a plasma processing system of a second embodiment.

FIG. 12 is a view illustrating an example of a plasma processing system of a third embodiment.

FIG. 13 is a view illustrating an example of a plasma processing system of a fourth embodiment.

FIG. 14 is a view illustrating an example of a plasma processing system of a fifth embodiment.

### DETAILED DESCRIPTION

Hereinafter, non-limiting exemplary embodiments of the present disclosure will be described with reference to the accompanying drawings. In the drawings, the same or corresponding members or components are denoted by the same or corresponding reference symbols, and overlapping descriptions thereof will be omitted.

### First Embodiment

### Plasma Processing System

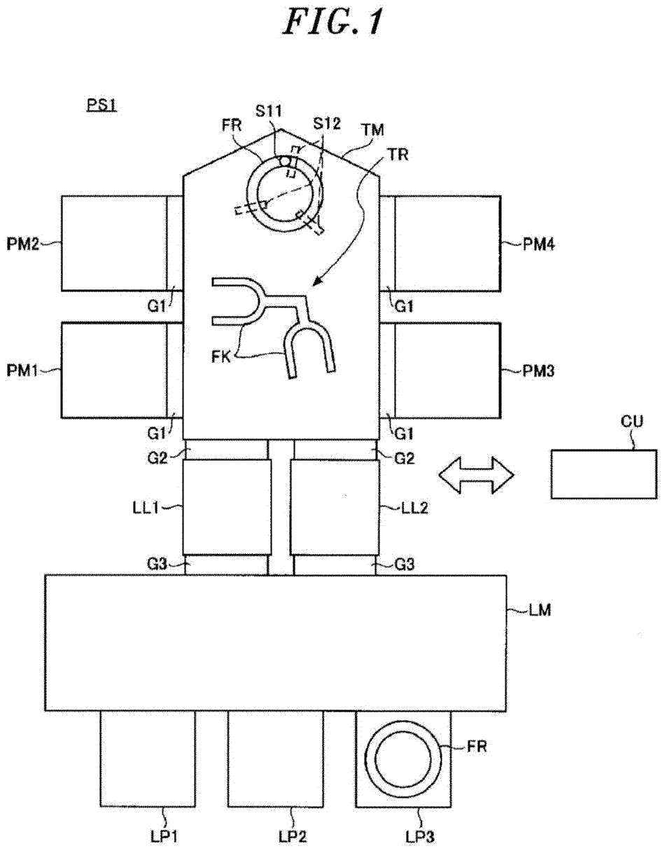

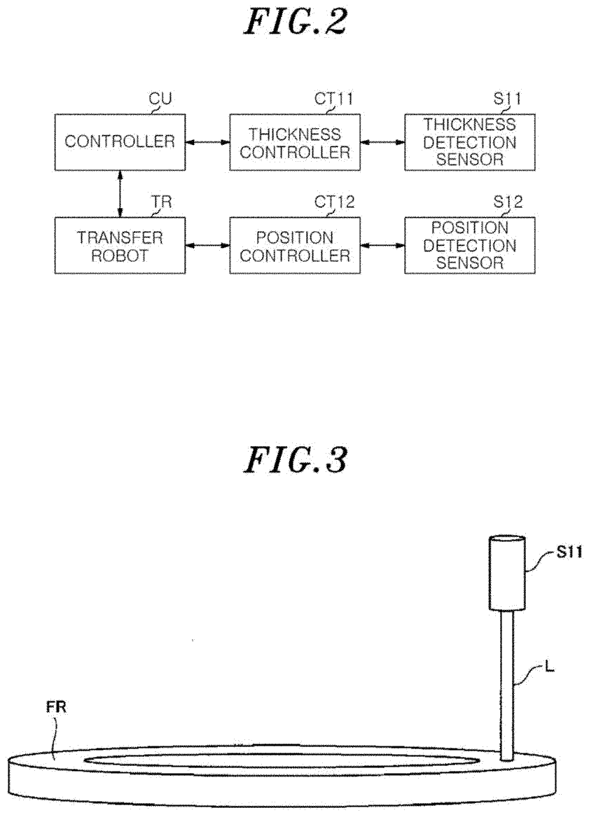

An example of a plasma processing system of a first embodiment will be described with reference to FIGS. 1 to 3. A plasma processing system PS1 of the first embodiment is a system capable of performing various types of processing such as plasma processing on a substrate.

The plasma processing system PS1 includes a vacuum transfer chamber TM, process modules PM1 to PM4, load-lock chambers LL1 and LL2, an atmospheric transfer chamber LM, a controller CU, and the like.

The vacuum transfer chamber TM has a substantially pentagonal shape in a plan view. In the vacuum transfer chamber TM, the process modules PM1 to PM4 are connected to two opposite side surfaces. The load-lock chambers LL1 and LL2 are connected to one side surface of the other two opposite side surfaces of the vacuum transfer chamber TM, and the thickness detection sensor S11 and a position detection sensor S12 are provided in the vicinity of the other side surface. The vacuum transfer chamber TM has a vacuum, chamber, and a transfer robot TR is disposed inside the chamber.

The transfer robot TR is configured to be rotatable, extensible, and movable vertically. The transfer robot TR places a transfer target object on a fork FK disposed at a distal end and transfers the transfer target object between the load-lock chambers LL1 and LL2 and the process modules PM1 to PM4. The transfer target object includes a substrate and a consumable member. The substrate may be, for example, a semiconductor wafer. The consumable member is a member that is attached in the process nodules PM1 to FM4 in a replaceable manner, and is consumed when various types of processing such as plasma processing are performed in the process modules PM1 to PM4. The consumable member includes, for example, an edge ring FR, a cover ring, and a top plate of an upper electrode. The edge ring FR is an annular member disposed around the substrate in the process modules PM1 to PM4. The cover ring is an annular member placed on an outer periphery of the edge ring FR and formed of quartz or the like. The top plate of the upper electrode is a plate-shaped member in which a plurality of gas introduction ports (not illustrated) are formed.

For example, as illustrated in FIG. 3, the thickness detection sensor S11 detects a signal (for example, reflected light) from the edge ring FR when light L is projected onto the edge ring FR. Further, the thickness detection sensor S11 transmits a detection signal to a thickness controller CT11. The thickness detection sensor S11 may be provided inside the vacuum transfer chamber TM or may be provided outside the vacuum transfer chamber TM. The thickness detection sensor S11 is a non-contact sensor, and may be, for example, a spectral interference type thickness sensor or a displacement sensor. Examples of the spectral interference type thickness sensor include a wavelength sweep type interferometer and a multichannel spectral interferometer. Examples of the displacement sensor include a triangulation type (PSD type, CMOS type, CCD type) sensor, a coaxial confocal type sensor, a white coaxial confocal type sensor, and a photo-cutting type sensor. In the example of FIG. 3, a case where the thickness detection sensor S11 detects the thickness of the edge ring FR from above the edge ring FR has been described. However, the present disclosure is not limited thereto. For example, the thickness detection sensor S11 may be configured to detect the thickness of the edge ring FR from below the edge ring FR. Further, for example, the thickness detection sensor S11 may be configured to detect the thickness of the edge ring FR from both sides (upper and lower) of the edge ring FR. The detection of the thickness of the edge ring FR from both sides of the edge ring FR may increase accuracy of the detected thickness of the edge ring FR.

The thickness controller CT11 calculates the thickness of the edge ring FR based on the detection signal from the thickness detection sensor S11. The thickness controller CT11 outputs the calculated thickness of the edge ring FR to the controller CU.

The position detection sensor S12 detects the position of the transfer target object held by the fork FK, and transmits a detection signal to the position controller CT12. The position detection sensor S12 detects the position of the substrate held by the fork FK, for example, by detecting a plurality of locations on an outer peripheral portion of the substrate. Further, for example, the position detection sensor S12 detects the positions of the edge ring FR held by the fork FK by detecting a plurality of positions of an inner peripheral portion of the edge ring FR.

The position controller CT12 calculates a misalignment amount of the transfer target, object from a reference position based on the position of the transfer target object detected by the position detection sensor S12 and a predetermined reference position, and transmits the calculated misalignment amount to the controller CU. The controller CU controls the transfer robot TR so that the transfer target object is placed on a stage of a transfer destination (for example, the process modules PM1 to PM4) to correct the calculated misalignment amount.

The process modules PM1 to FM4 each have a processing chamber and have a stage disposed inside the chamber. After the substrate is placed on the stage, the process modules PM1 to PM4 each are decompressed interiorly to introduce a processing gas thereinto, an RF power is applied to generate plasma, and plasma processing is performed on the substrate by the generated plasma. Examples of the plasma processing include an etching process. The vacuum transfer chamber TM and the process modules PM1 to PM4 are separated by openable/closable gate valves G1.

The load-lock chambers LL1 and LL2 are disposed between the vacuum transfer chamber TM and the atmospheric transfer chamber LM. Each of the load-lock chambers LL1 and LL2 has an internal pressure variable chamber of which the inside can be switched between vacuum and atmospheric pressure. Here, the vacuum refers to a low-pressure state in which the pressure is reduced below the atmospheric pressure. The load-lock chambers LL1 and LL2 each have a stage disposed inside. When the substrate is loaded from the atmospheric transfer chamber LM into the vacuum transfer chamber TM, the load-lock chambers LL1 and LL2 each receive the substrate from the atmospheric transfer chamber LM while maintaining the inside at the atmospheric pressure, switch the inside to vacuum, and load the substrate into the vacuum transfer chamber TM. When the substrate is unloaded from the vacuum transfer chamber TM into the atmospheric transfer chamber LM, the load-lock chambers LL1 and LL2 each receive the substrate from the vacuum transfer chamber TM while maintaining the vacuum in the inside thereof, and load the substrate into the atmospheric transfer chamber LM while raising the internal pressure to the atmospheric pressure. The load-lock chambers LL1 and LL2 and the vacuum transfer chamber TM are separated by openable/closable gate valves G2. The load-lock chambers LL1 and LL2 and the atmospheric transfer chamber LM are separated by openable/closable gate valves G3.

The atmospheric transfer chamber LM is disposed to face the vacuum transfer chamber TM. The atmospheric transfer chamber LM may be, for example, an equipment front end module (EFEM). The atmospheric transfer chamber LM has a rectangular parallelepiped shape and includes an FFU (Fan Filter Unit), and is an atmospheric transfer chamber maintained at an atmospheric pressure. Two load-lock chambers LL1 and LL2 are connected to one side surface of the atmospheric transfer chamber LM in a longitudinal direction. Load ports LP1 to LP3 are connected to the other side surfaces of the atmospheric transfer chamber LM in the Longitudinal direction. Containers for accommodating transfer target objects are placed in the load ports LP1 to LP3. The container includes, for example, a container that accommodates one or more substrates and a container that accommodates one or more consumable members. The container accommodating the substrate may be, for example, a front-opening unified pod (FOUP). The container that accommodates the consumable member includes, for example, a container that accommodates the edge ring FR, a container that accommodates the cover ring, and a container that accommodates the top plate of the upper electrode. A transfer robot (not illustrated) is disposed in the atmospheric transfer chamber LM. The transfer robot transfers a transfer target object between the containers placed at the load ports LP1 to LP3 and the internal pressure variable chambers of the load-lock chambers LL1 and LL2. The example of FIG. 1 illustrates a case that the container accommodating the edge ring FR is placed at the load port LP3.

The controller CU controls each part of the plasma processing system PS1, for example, the transfer robot TR provided in the vacuum transfer chamber TM, the transfer robot provided in the atmospheric transfer chamber LM, and the gate valves G1 to G3. Further, the controller CU controls each part of the plasma processing system PS1 to execute a measurement method of an embodiment to be described later. The controller CU includes a central processing unit (CPU), a random access memory (RAM), a read only memory (ROM), an auxiliary storage device, and the like. The CPU operates based on a program stored in the ROM or the auxiliary storage device, and controls each part of the plasma processing system PS1.

### Plasma Processing Apparatus

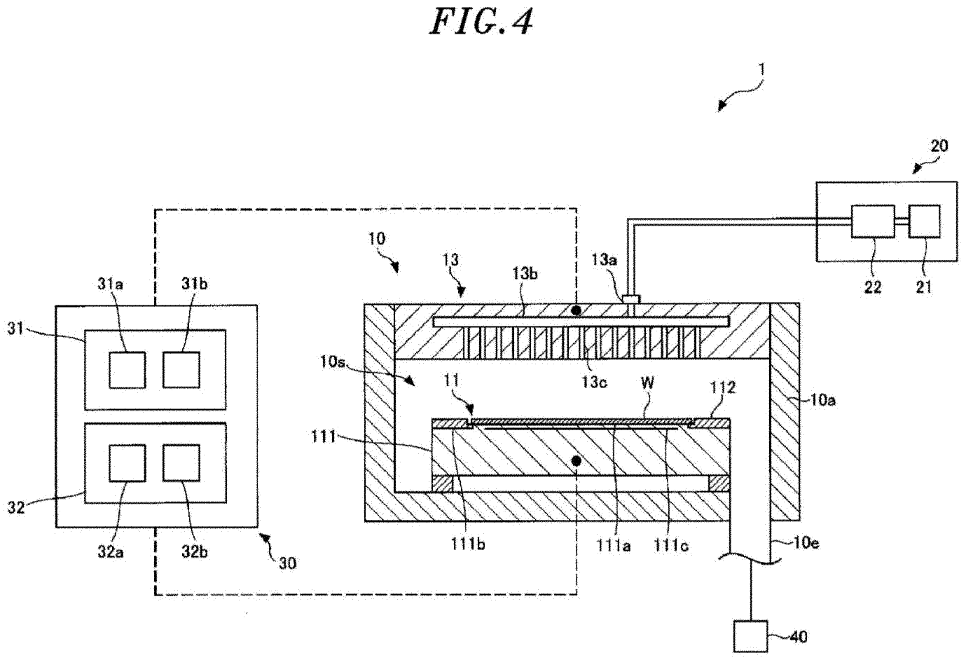

An example of a plasma processing apparatus used as the process modules PM1 to PM4 provided in the plasma processing system PS1 of FIG. 1 will be described with reference to FIG. 4.

A plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, arid at least one gas exhaust port for exhausting the gas from the plasma processing space. The sidewall 10a is grounded. The shower head 13 and the substrate support 11 are electrically insulated from a housing of the plasma processing chamber 10.

The substrate support 11 includes a main body 111 and a ring assembly 112. The main body 111 has a central region (substrate support surface) 111a for supporting the substrate (wafer) W, and an annular region (ring support surface) 111b for supporting the ring assembly 112. The annular region 111b of the main body 111 surrounds the central region 111a of the main body 111 in a plan view. The substrate W is disposed on the central region 111a of the main body, 111 and the ring assembly 112 is disposed on the annular region 111b of the main body 111 to surround the substrate W on the central region 111a of the main body 111. In one embodiment, the main body 111 includes a base and an electrostatic chuck. The base includes a conductive member. The conductive member of the base functions as a lower electrode. The electrostatic chuck is disposed on the base. The upper surface of the electrostatic chuck has a substrate support surface 111a. The electrostatic chuck has, for example, a configuration in which an adsorption electrode 111c is interposed between insulators The ring assembly 112 includes one or more annular members. At least one of the one or more annular members is the edge ring FR. Although not illustrated, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid such as a coolant or a gas flows through the flow path. Further, the substrate support 11 may include a heat transfer gas supply configured to supply a heat transfer gas between the rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power), such as the source RF signal and the bias RF signal, to the conductive member of the substrate support 11 and/or the conductive member of the shower head 13. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying of the bias RF signal to the conductive member of the substrate support 11 can generate a bias potential in the substrate W to draw an ion component in the formed plasma to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit, and configured to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The generated one or more source RF signals are supplied to the conductive member of the substrate support 11 and/or the conductive member of the shower head 13. The second RF generator 31b is coupled to the conductive member of the substrate support 11 via at least one impedance matching circuit, and configured to generate a bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and configured to generate a first DC signal. The generated first bias DC signal is applied to the conductive member of the substrate support 11. In one embodiment, the first DC signal may be applied to another electrode, such as an electrode in an electrostatic chuck. In one embodiment, the second DC generator 32b is connected to the conductive member of the shower head 13 and configured to generate a second DC signal. The generated second DC signal is applied to the conductive member of the shower head 13. In various embodiments, at least one of the first, and second DC signals may be pulsed. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### Lifter

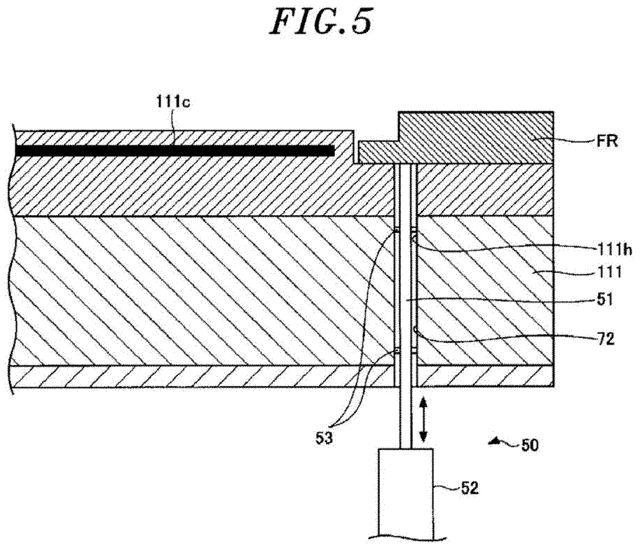

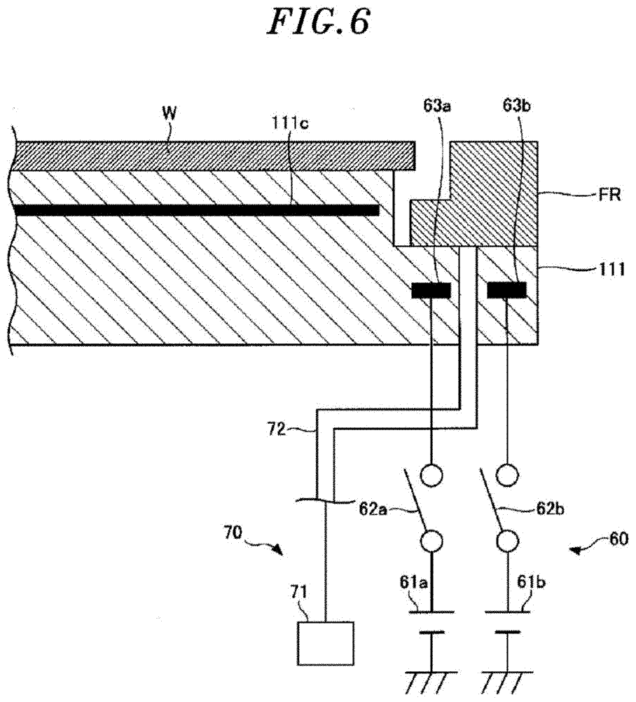

An example of a lifter for raising or lowering the edge ring FR in the plasma processing apparatus 1 will be described with reference to FIG. 5.

A lifter 50 raises or lowers the edge ring FR. The lifter 50 includes a raising/lowering pin 51, an actuator 52, and a sealing member 53.

The raising/lowering pin 51 is inserted into a through-hole 111h extending through the main body 111 in the vertical direction immediately below the edge ring FR. A distal end (first end) of the raising/lowering pin 51 abuts on the bottom surface of the edge ring FR. A base end (second end) of the raising/lowering pin 51 is supported by an actuator 52 disposed outside the plasma processing chamber 10.

The actuator 52 moves the raising/lowering pin 51 up and down to adjust a height position of the edge ring FR.

The sealing member 53 is provided between an inner wall of the through-hole 111h and the raising/lowering pin 51. The sealing member 53 seals a space between the inner wall of the through-hole 111h and the raising/lowering pin 51 in an airtight manner. The sealing member 53 may be, for example, an O-ring.

When the edge ring FR is unloaded, first, the raising/lowering pin 51 is moved up and down by the actuator 52 to adjust the height position of the edge ring FR. Subsequently, the gate valve G1 is opened, and the fork FK enters below the edge ring FR in the plasma processing chamber 10. Subsequently, the raising/lowering pin 51 is lowered no place the edge ring FR on the fork FK.

When the edge ring FR is loaded, first, the gate valve G1 is opened, and the fork FK holding the edge ring FR enters the plasma processing chamber 10. Subsequently, the edge ring FR on the fork FK is delivered onto the raising/lowering pin 51 by raising the raising/lowering pin 51 by the actuator 52.

### Adsorption Mechanism and Heat Transfer Gas Supply Mechanism

With reference to FIG. 6, an adsorption mechanism that adsorbs the edge ring FR in the plasma processing apparatus 1 and a heat transfer gas supply mechanism that supplies a heat transfer gas to the rear surface of the edge ring FR will be described by way of example.

The adsorption mechanism 60 includes direct-current (DC) power sources 61a and 61b, switches 62a and 62b, and electrode plates 63a and 63b. The adsorption mechanism 60 generates an electrostatic force such as a Coulomb force by the voltages applied from the DC power sources 61a and 61b to the electrode plates 63a and 63b, and adsorbs the edge ring FR on the main body 111 by the electrostatic force. FIG. 6 illustrates an example in which the electrode plate is a bipolar electrode. However, the electrode plate may be a unipolar electrode.

The heat transfer gas supply mechanism 70 includes a heat transfer gas supply source 71 and a gas supply line 72. The heat transfer gas supply source 71 supplies the heat transfer gas to the gas supply line 72. As the heat transfer gas, a gas having thermal conductivity, for example, helium (He) gas or the like is preferably used. One end of the gas supply line 72 is connected to the heat transfer gas supply source 71, and the other end thereof communicates between the upper surface of the main body 111 and the bottom surface of the edge ring FR. The heat transfer gas supply mechanism 70 supplies a heat transfer gas from the heat transfer gas supply source 71 to a space between the upper surface of the main body 111 and the bottom surface of the edge ring FR through the gas supply line 72.

### Bias Power Source

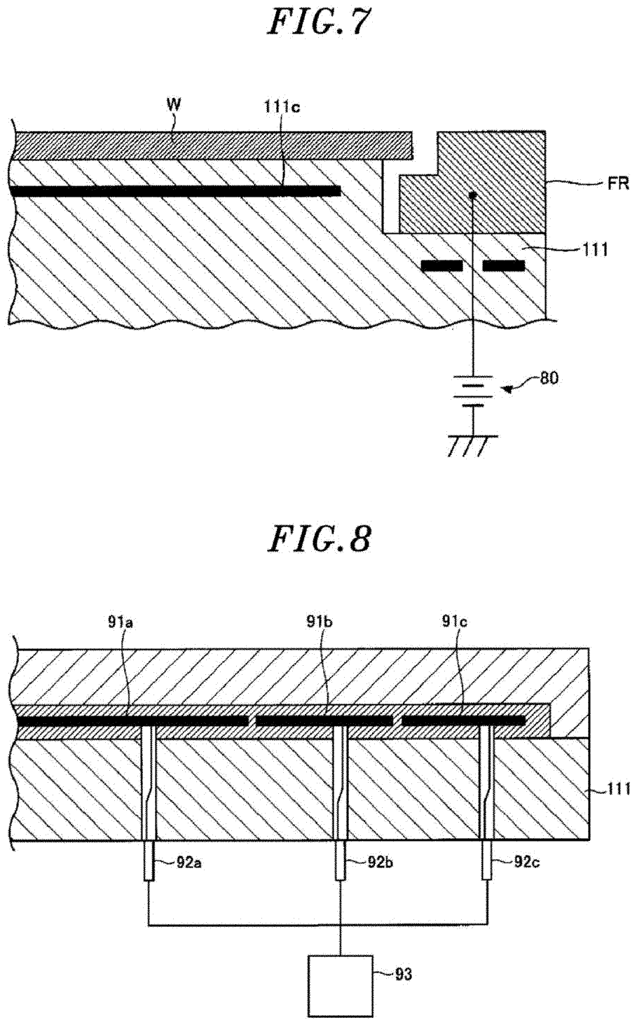

Referring to FIG. 7, an example of a bias power source that applies a bias voltage to the edge ring FR in the plasma processing apparatus 1 will be described.

The bias power source 80 is connected to the edge ring FR. The bias power source 80 is configured to apply a DC voltage of, for example, 10 to 500 V to the edge ring FR. During the plasma processing, the bias power source 80 can adjust a thickness of a plasma sheath above the edge ring FR by applying a predetermined voltage to the edge ring FR to correct distortion of the plasma sheath at an end portion of the substrate W. As a result, it is possible to improve the uniformity of an etching shape in the surface of the substrate W. Further, during the plasma processing, the bias power source 80 changes the bias voltage to be applied to the edge ring FR based on the thickness of the edge ring FP. detected in a transfer method to be described later. Accordingly, even when the thickness of the edge ring FR is changed due to the wear of the edge ring FR, the distortion of the plasma sheath at the end portion of the substrate W may be corrected. Therefore, it is possible to suppress the change of the etching shape in the surface of the substrate W due to the wear of the edge ring FR. As the bias power source 80, in addition to the DC power source, a radio-frequency power source of 400 kHz to 100 MHz may be used.

### Heating Mechanism

An example of a heating mechanism for heating the substrate W in the plasma processing apparatus 1 will be described with reference to FIG. 8.

The heating mechanism (heater) 90 is embedded in the main body 111. The heating mechanism 90 includes a plurality of heaters 91a to 91c, power feed lines 92a to 92c, and an alternating-current (AC) power source 93. For example, the heaters 91a to 91c are provided in a central region, an intermediate region, and a peripheral region of the main body 111, respectively, respective ends of the power feed lines 92a to 92c are connected to the heaters 91a to 91c, and the other ends of the power feed lines 92a to 92c are connected to the AC power source 93. The AC power source 93 supplies a predetermined current to the heaters 91a to 91c through the power feed lines 92a to 92c. As a result, the temperature of the main body 111 can be raised for each region.

The above-described adsorption mechanism 60, the heat transfer gas supply mechanism 70, the bias supply (the application of the bias voltage to the edge ring FR by the bias power source 80), and the heating mechanism 90 may be combined appropriately.

### Transfer Method

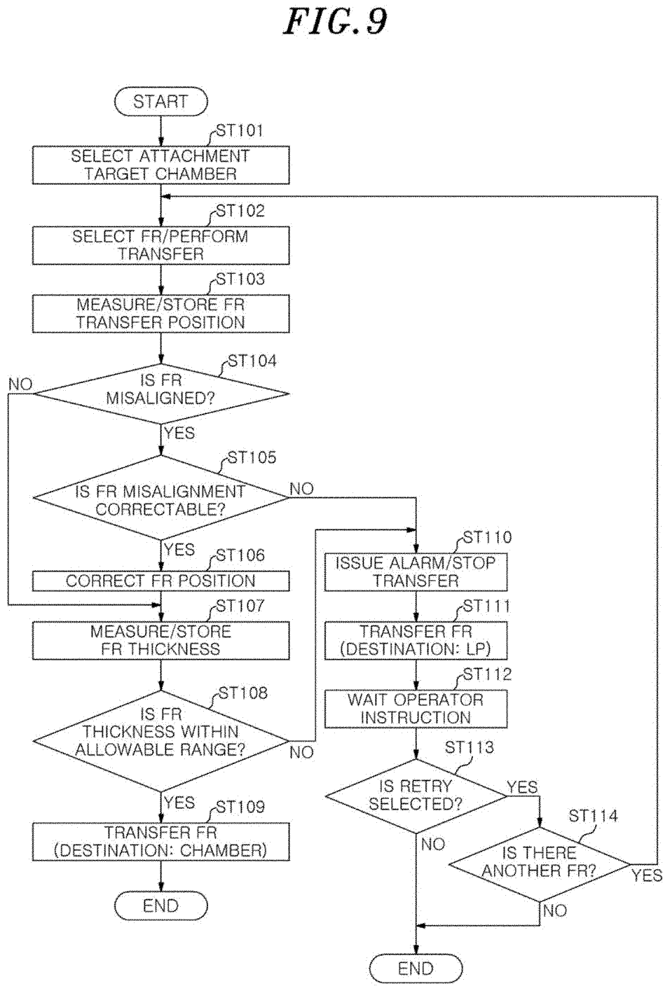

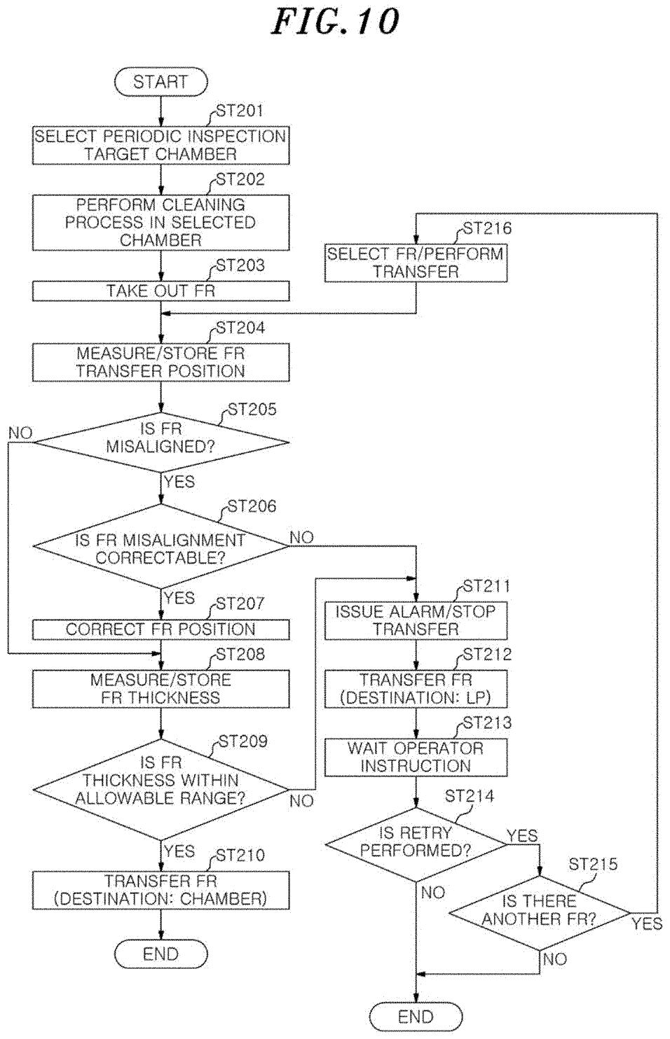

An example of a transfer method of one embodiment will be described with reference to FIG. 9. Hereinafter, in the plasma processing system PS1 illustrated in FIG. 1, a case where the edge ring FR is installed in the stage in the process module PM1 where the edge ring FR is not installed will be described by way of example.

In Step ST101, the controller CU selects an attachment target chamber of the edge ring FR. For example, the controller CU selects the process module PM1 as the attachment target chamber of the edge ring FR.

In Step ST102, the controller CU selects the edge ring FR, and starts the transfer of the selected edge ring FR. In one embodiment, first, the controller CU controls the transfer robot, (not illustrated) in the atmospheric transfer chamber LM to unload the edge ring FR accommodated in, for example, the container placed at the load port LP3. Subsequently, the controller CU controls the gate valve G3 between the atmospheric transfer chamber LM and the load-lock chamber LL1 to be opened. Subsequently, the controller CU controls the transfer robot to place the edge ring FR on the stage in the load-lock chamber LL1. Subsequently, the controller CU executes control of closing the gate valve G3, reducing the pressure in the load-lock chamber LL1, and switching the state of the load-lock chamber LL1 to a vacuum state. Subsequently, the controller CU executes control of opening the gate valve G2 between the load-lock chamber LL1 and the vacuum transfer chamber TM. Subsequently, the controller CU executes control so that the fork FK of the transfer robot TR disposed in the vacuum transfer chamber TM receives the edge ring FR placed on the stage in the load-lock chamber LL1.

In Step ST103, the controller CU detects the position of the edge ring FR during the transfer. In one embodiment, the controller CU controls the transfer robot TR to move the fork FK holding the edge ring FR to a detection region of the position detection sensor S12 provided in the vacuum transfer chamber TM. Subsequently, the position controller CT12 detects the position of the edge ring FR by the position detection sensor S12. Further, the position controller CT12 may store (save) the detected position of the edge ring FR.

In Step ST104, the controller CU determines whether or not there is misalignment of the edge ring FR based on the position of the edge ring FR detected in Step ST103. In one embodiment, the position controller CT12 calculates a misalignment, amount of the edge ring FR from the reference position based on the position of the edge ring FR detected by the position detection sensor S12 and a predetermined reference position, and transmits the calculated misalignment amount to the controller CU. The controller CU determines whether or not there is the misalignment of the edge ring FR based on the misalignment amount. When it is determined in Step ST104 that the edge ring FR is misaligned, the controller CU advances the processing to Step ST105. When it is determined in Step ST104 that the edge ring FR is not misaligned, the controller CU advances the processing to Step ST107.

In Step ST105, the controller CU determines whether the misalignment calculated in Step ST104 is correctable or not. When it is determined in Step ST105 that the misalignment is correctable, the controller CU advances the processing to Step ST106. Meanwhile, when it is determined in Step ST105 that the misalignment is not correctable, the controller CU advances the processing to Step ST110.

In step S106, the controller CU corrects the misalignment amount of the edge ring FR or calculates a correction value based on the misalignment amount calculated in Step ST104.

In Step ST107, the controller CU detects the thickness of the edge ring FR. In one embodiment, the controller CU controls the transfer robot IR to move the fork FK holding the edge ring FR to the detection region of the thickness detection sensor S11 provided in the vacuum transfer chamber TM in consideration of the correction value. The detection region of the thickness detection sensor S11 may be located at the same position as the detection region of the position detection sensor S12, or may be located at a different position. When the detection region of the thickness detection sensor S11 is located at the same position as the detection region of the position detection sensor S12, the thickness of the edge ring FR can foe detected without moving the fork FK after the position of the edge ring FR is detected.

In Step ST108, the controller CU determines whether the thickness of the edge ring FR is within an allowable range or not. In one embodiment, the controller CU determines whether the thickness of the edge ring FR is within the allowable range or not, based on the thickness of the edge ring FR detected in Step ST107. When it is determined in Step ST108 that the thickness of the edge ring FR is within the allowable range, the controller CU advances the processing to Step ST109. When it is determined in Step ST108 that the thickness of the edge ring FR is outside the allowable range, the controller CU advances the processing to Step ST110.

In Step ST109, the controller CU transfers the edge ring FR to the process module PM1. In one embodiment, first, the controller CU executes control of opening the gate valve G1 between the vacuum transfer chamber TM and the process module PM1. Subsequently, the controller CU controls the transfer robot TR to place the edge ring FR on the stage of the process module PM1 so as to correct the misalignment amount calculated by the position controller CT12. Thereafter, the controller CU ends the processing.

Further, when plasma processing is performed on the substrate W after the new edge ring FR is placed on the stage of the process module PM1, the controller CU may apply the plasma processing under conditions set based on the thickness of the edge ring FR calculated by the thickness controller CT11. This enables to improve the uniformity of the plasma processing.

The condition for the plasma processing may be, for example, a magnitude of the bias voltage that is supplied to the edge ring FR by the bias power source 80. Further, the condition for the plasma processing may be, for example, a lifting amount of the edge ring FR by the raising/lowering pin 51. Further, the condition for the plasma processing may be, for example, the supply pressure or the supply flow rate of the heat transfer gas supplied between the upper surface of the main body 111 and the bottom surface of the edge ring FR by the heat transfer gas supply mechanism 70. Further, the condition for the plasma processing may be, for example, a set temperature of the heater 91c that heats a peripheral region of the main body 111.

In Step ST110, the controller CU issues an alarm and stops the transfer of the edge ring FR by the transfer robot TR.

In Step ST111, the controller CU transfers the edge ring FR to any of the load ports LP1 to LP3. In one embodiment, first, the controller CU executes control of reducing the pressure in the load-lock chamber LL2 to switch the state of the load-lock chamber LL2 to a vacuum state. Subsequently, the controller CU executes control of opening the gate valve G2 between the load-lock chamber LL2 and the vacuum transfer chamber TM. Subsequently, the controller CU executes control so that the edge ring FR held by the fork FK of the transfer robot TR is placed on the stage in the load-lock chamber LL2. Subsequently, the controller CU executes control of closing the gate valve G2 and switching the inside of the load-lock chamber LL2 to the atmosphere. Subsequently, the controller CU executes control of opening the gate valve G3 between the atmospheric transfer chamber LM and the load-lock chamber LL2 to be opened. Subsequently, the controller CU executes control such that the transfer robot (not illustrated) in the atmospheric transfer chamber LM receives the edge ring FR placed on the stage in the load-lock chamber LL2; for example, the edge ring FR is accommodated in a container placed in the load port LP3. Further, the controller CU executes control of closing the gate valve G3.

In Step ST112, the controller CU shifts the state of the plasma processing system PS1 to an operator-instruction waiting state.

In Step ST113, the controller CU determines whether “retry” or “not to retry” has been selected by the operator. When it is determined in Step ST113 that the “retry” has been selected, the controller CU advances the processing to Step ST114. When it is determined in Step ST113 that “not to retry” has been selected, the controller CU ends the processing.

In Step ST114, the controller CU determines whether or not there is another edge ring FR that can be used. When it is determined in Step ST114 that there is another edge ring FR that can be used, the controller CU returns the processing to Step ST102. Meanwhile, when it is determined in Step ST114 that there is no other edge ring FR that can be used, the controller CU ends the processing.

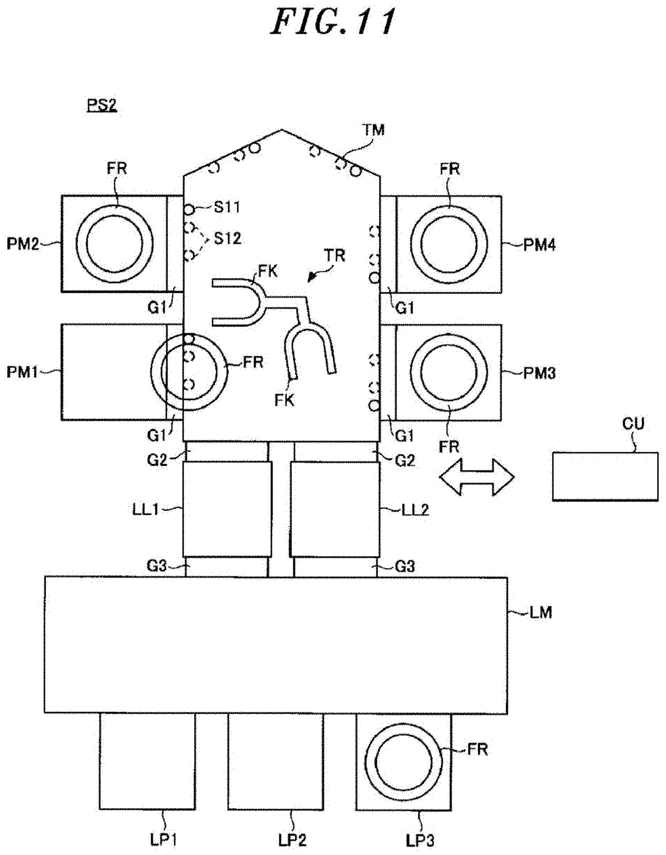

Another example of the transfer method of the embodiment will be described with reference to FIG. 10. Hereinafter, a case where the plasma processing system PS1 illustrated in FIG. 1 performs periodic inspection and replacement of the edge ring FR installed in the stage in the process module PM1 will be described as an example.

In Step ST201, the controller CU selects an inspection target chamber for the edge ring FR. For example, the controller CU selects the process module PM1 as the inspection target chamber for the edge ring FR.

In Step ST202, the controller CU executes cleaning processing in the chamber selected in Step ST201. For example, the controller CU executes control so that the adsorption of the edge ring FR on the main body 111 is released by turning off the voltages applied from the DC power sources 61a and 61b of the adsorption mechanism 60 to the electrode plates 63a and 63b. Subsequently, preferably, the controller CU executes control of cleaning processing in a state where the edge ring FR placed on the stage in the process module PM1 is lifted by the raising/lowering pin 51 and separated from a stage placement surface. As a result, reaction products deposited on the rear surface of the edge ring FR through plasma processing can be removed. Alternatively, the controller CU may execute control of the cleaning processing without separating the edge ring FR from the stage placement surface. The cleaning processing refers to processing of removing deposits in the process module PM1 generated by the plasma processing by plasma or the like of a processing gas to stabilize the inside of the process module PM1 in a clean state. Application of the cleaning processing can suppress deposits in the process module PM1 from being stirred up when the edge ring FR is unloaded from the inside of the process module PM1. As the processing gas, for example, an oxygen (O₂) gas, a fluorocarbon (CF)-based gas, a nitrogen (N₂) gas, an argon (Ar) gas, a He gas, or a mixed gas of two or more of these can be used. Further, when the cleaning processing of the process module PM1 is performed, in order to protect the electrostatic chuck of the stage, the cleaning processing may be performed in a state where the substrate W such as a dummy wafer is placed on the upper surface of the electrostatic chuck, depending on the processing conditions. When there is no deposit in the process module PM1 or when there is no influence on the transfer of the edge ring, the cleaning processing may be omitted. That is, Step ST202 may be omitted.

In Step ST203, the controller CU executes control so that the edge ring FR is taken out from the inside of the process module PM1. In one embodiment, first, the controller CU executes control of opening the gate valve G1 between the vacuum transfer chamber TM and the process module PM1. Subsequently, the controller CU executes control so that the fork FK of the transfer robot TR disposed in the vacuum transfer chamber TM receives the edge ring FR placed on the stage in the process module PM1. More specifically, first, the edge ring FR is lifted at the distal end of the raising/lowering pin 51 by raising the raising/lowering pin 51 by the actuator 52. Subsequently, the fork FK enters below the edge ring FR in the process module PM1. Subsequently, the raising/lowering pin 51 is lowered to place the edge ring FR on the fork FK. Subsequently, the controller CU executes control of transferring the edge ring FR to the vacuum transfer chamber TM and closing the gate valve G1.

Steps ST204 to ST215 may be the same as steps ST103 to ST114 described above. Further, Step ST216 may be the same as Step ST102 described above.

According to the first embodiment described above, the thickness detection sensor S11 for detecting the thickness of the edge ring FR is provided in the vacuum transfer chamber TM outside the process modules PM1 to PM4 of the plasma processing system PS1. Accordingly, it is possible to detect the amount of consumption of the edge ring FR in an environment where the edge ring FR is not exposed to plasma. As a result, the thickness of the edge ring FR can be detected with high accuracy.

In contrast, in a case where the thickness detection sensors are provided in the process modules PM1 to PM4, for example, a view port through which light is transmitted is provided in the top plate or the sidewall of the process module PM1, and the edge ring FR is exposed to light through the view port so as to detect the thickness of the edge ring FR. In this case, since the view port can be etched by plasma, the view port becomes a new consumable member. Then, maintenance for periodically replacing the view port newly occurs; thus, productivity decreases, and the cost increases. Further, when a surface of the view port is consumed or an etching product adheres to the surface of the view port, the signal-to-noise ratio of the detection value is reduced, which deteriorates the detection accuracy.

Further, according to the first embodiment, the thickness of the edge ring FR is detected before the edge ring FR is placed on the stage of the process module PM1. When the detected thickness of the edge ring FR is within the allowable range, the edge ring FR is placed on the stage of the process module PM1. Meanwhile, when the detected thickness of the edge ring FR is outside the allowable range, the edge ring FR is retrieved and replaced. As a result, it is possible to prevent an error in attaching of the edge ring FR.

### Second Embodiment

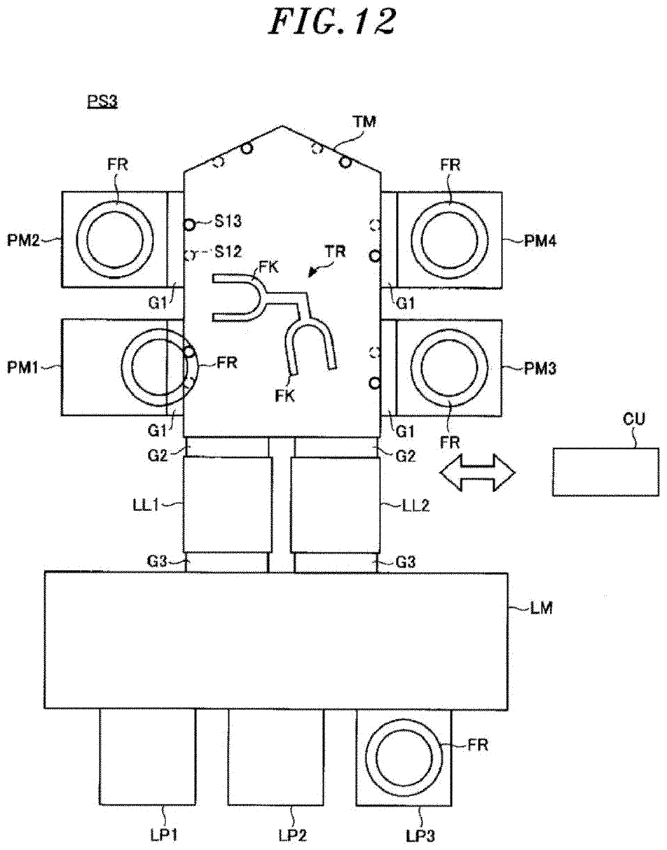

An example of a plasma processing system of a second embodiment will be described with reference to FIG. 11. A plasma processing system PS2 of the second embodiment is different from the plasma processing system PS1 of the first embodiment in that a thickness detection sensor S11 and a position detection sensor S12 are provided in the vicinity of a gate valve G1. Other aspects may be the same as those of the plasma processing system PS1 of the first embodiment.

The thickness detection sensor S11 is provided in the vicinity of the gate valve G1 between the vacuum transfer chamber TM and each of the process modules PM1 to PM4. The thickness detection sensor S11 detects the thickness of the edge ring FR in a transfer path through which the fork FK of the transfer robot TR transfers the edge ring FR between the vacuum transfer chamber TM and each of the process modules PM1 to PM4.

The position detection sensor S12 is provided in the vicinity of the gate valve G1 between the vacuum transfer chamber TM and each of the process modules PM1 to PM4. The position detection sensor S12 detects the position of the edge ring FR in a transfer path through which the fork FK of the transfer robot TR transfers the edge ring FR between the vacuum transfer chamber TM and each of the process modules PM1 to PM4.

According to the second embodiment, the thickness detection sensor S11 for detecting the thickness of the edge ring FR is provided in the vacuum transfer chamber TM outside the process modules PM1 to PM4 of the plasma processing system PS2. Accordingly, it is possible to detect the amount of consumption of the edge ring FR in an environment where the edge ring FR is not exposed to plasma. As a result, the thickness of the edge ring FR can be detected with high accuracy.

Further, according to the second embodiment, the thickness of the edge ring FR is detected before the edge ring FR is placed on the stage of the process module PM1. When the detected thickness of the edge ring FR is within the allowable range, the edge ring FR is placed on the stage of the process module PM1. Meanwhile, when the detected thickness of the edge ring FR is outside the allowable range, the edge ring FR is retrieved and replaced. As a result, it is possible to prevent an error in attaching of the edge ring FR.

Further, according to the second embodiment, the thickness detection sensor 311 and the position detection sensor S12 are provided in the vicinity of the gate valve G1 between the vacuum transfer chamber TM and each of the process modules PM1 to PM4. Therefore, the transfer robot TR can calculate the thickness and misalignment of the edge ring FR while transferring the edge ring FP from the vacuum transfer chamber TM to the process modules PM1 to PM4. Therefore, throughput of the edge ring transfer is improved compared with the plasma processing system PS1.

### Third Embodiment

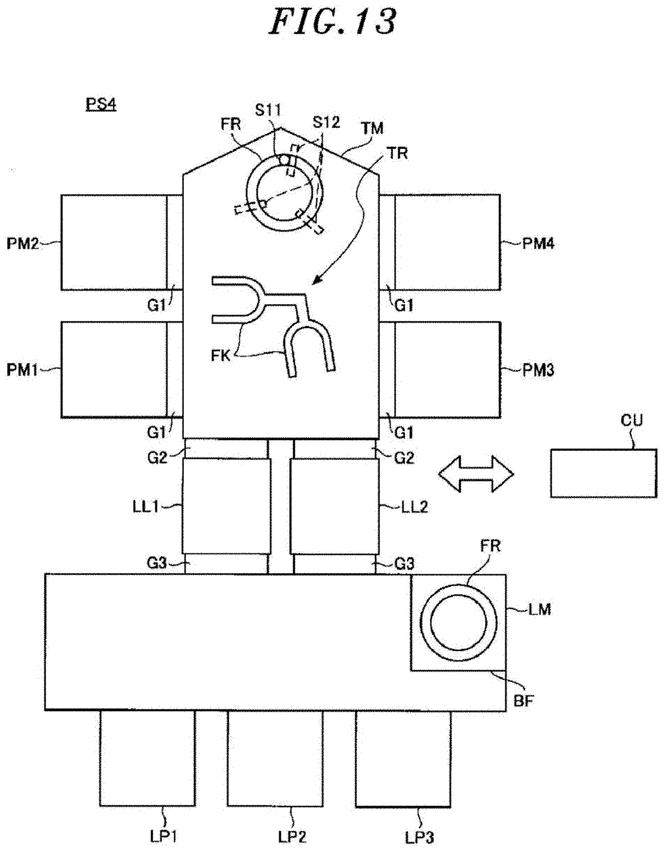

An example of a plasma processing system of a third embodiment will be described with reference to FIG. 12. A plasma processing system PS3 of the third embodiment is different from the plasma processing system PS2 of the second embodiment in that a function of a thickness detection sensor S11 is integrated with a position detection sensor S12. Other aspects may be the same as those of the plasma processing system PS2 of the second embodiment.

The plasma processing system PS3 includes a position detection sensor S12 and a combined detection sensor S13 provided in the vicinity of a gate valve G1 between a vacuum transfer chamber TM and each of process modules PM1 to PM4.

The combined detection sensor S13 has a function of detecting a position of an edge ring FR and a function of detecting a thickness of an edge ring FR.

According to the third embodiment, the thickness detection sensor S11 for detecting the thickness of the edge ring FR is provided in the vacuum transfer chamber TM outside the process modules PM1 to PM4 of the plasma processing system PS3. Accordingly, it is possible to detect the amount of consumption of the edge ring FP in an environment where the edge ring FR is not exposed to plasma. As a result, the thickness of the edge ring FR can be detected with high accuracy.

Further, according to the third embodiment, the thickness of the edge ring FR is detected before the edge ring FR is placed on the stage of the process module PM1. When the detected thickness of the edge ring FR is within the allowable range, the edge ring FR is placed on the stage of the process module PM1. Meanwhile, when the detected thickness of the edge ring FR is outside the allowable range, the edge ring FR is retrieved and replaced. As a result, it is possible to prevent an error in attaching of the edge ring FR.

Further, according to the third embodiment, the position detection sensor S12 and the combined detection sensor S13 are provided in the vicinity of the gate valve G1 between the vacuum transfer chamber TM and each of the process modules PM1 to PM4. Therefore, the transfer robot TR can calculate the thickness and misalignment of the edge ring FR while transferring the edge ring FR from the vacuum transfer chamber TM to the process modules PM1 to PM4. Therefore, throughput of the edge ring transfer is improved compared with the plasma processing system PS1.

Further, according to the third embodiment, the function of the thickness detection sensor S11 is integrated with the position detection sensor S12. As a result, the number of sensors can be reduced.

### Fourth Embodiment

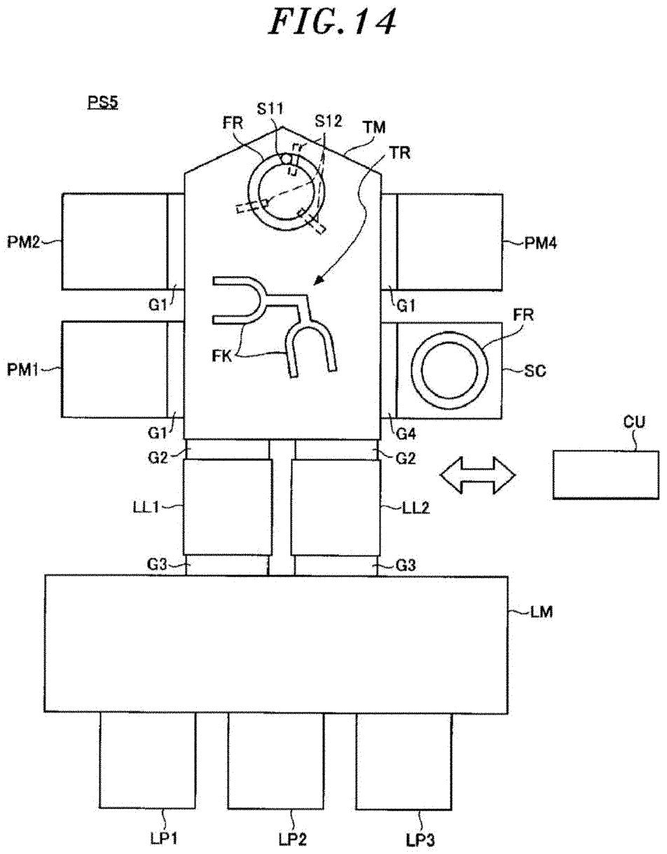

An example of a plasma processing system of a fourth embodiment will be described with reference to FIG. 13. A plasma processing system PS4 of the fourth embodiment is different from the plasma processing system PS1 of the first embodiment in that a buffer BF for storing an edge ring FR is provided in an atmospheric transfer chamber LM.

The buffer BF is provided in the atmospheric transfer chamber LM. The buffer BF accommodates a plurality of edge rings FR in multiple stages thereinside. The buffer BF is located at a position accessible by a transfer robot (not illustrated) in the atmospheric transfer chamber LM. The transfer robot transfers an edge ring FR between the buffer BF and each of load-lock chambers LL1 and LL2.

In this way, the other components may be identical to the plasma processing systems PS1 to PS3, except that the edge ring FR is accommodated in the buffer BF.

According to the fourth embodiment, the thickness detection sensor S1 1 for detecting the thickness of the edge ring FR is provided in the vacuum transfer chamber TM outside the process modules PM1 to PM4 of the plasma processing system PS4. Accordingly, it is possible to detect the amount of consumption of the edge ring FR in an environment where the edge ring FR is not exposed to plasma. As a result, the thickness of the edge ring FR can be detected with high accuracy.

Further, according to the fourth embodiment, the thickness of the edge ring FR is detected before the edge ring FR is placed on the stage of the process module PM1. When the detected thickness of the edge ring FR is within the allowable range, the edge ring FR is placed on the stage of the process module PM1. Meanwhile, when the detected thickness of the edge ring FR is outside the allowable range, the edge ring FR is retrieved and replaced. As a result, it is possible to prevent an error in attaching of the edge ring FR.

### Fifth Embodiment

An example of a plasma processing system of a fifth embodiment will be described with reference to FIG. 14. A plasma processing system PS5 of the fifth exemplary embodiment is different from the plasma processing system PS1 of the first exemplary embodiment in that a storage chamber SC for storing an edge ring FR is connected to a vacuum transfer chamber TM.

The storage chamber SC is connected to the vacuum transfer chamber TM through a gate valve G4. The storage chamber SC accommodates a plurality of edge rings FR in multiple stages thereinside. The storage chamber SC is located at a position accessible by the transfer robot TR. The transfer robot TR transfers the edge ring FR between the storage chamber SC and process modules PM1, PM2, and PM4.

In this way, the other components of the plasma processing systems PS1 to PS3 may be used, except that the edge ring FR is accommodated in the storage chamber SC.

According to the fifth embodiment, the thickness detection sensor S11 for detecting the thickness of the edge ring FR is provided in the vacuum transfer chamber TM outside the process modules PM1, PM2, and PM4 of the plasma processing system PS5. Accordingly, it is possible to detect the amount of consumption of the edge ring FR in an environment where the edge ring FR is not exposed to plasma. As a result, the thickness of the edge ring FR can be detected with high accuracy.

Further, according to the fifth embodiment, the thickness of the edge ring FR is detected before the edge ring FR is placed on the stage of the process module PM1. When the detected thickness of the edge ring FR is within the allowable range, the edge ring FR is placed on the stage of the process module PM1. Meanwhile, when the detected thickness of the edge ring FR is outside the allowable range, the edge ring FR is retrieved and replaced. As a result, it is possible to prevent an error in attaching of the edge ring FR.

It shall be understood that the embodiments disclosed herein are illustrative and are not restrictive in all aspects. The embodiments described above may be omitted, replaced, or modified in various forms without departing from the scope and spirit of the appended claims.

In the embodiments described above, the case of detecting the thickness of the edge ring FR has been described. However, the present disclosure is not limited thereto. For example, the present disclosure may be similarly applied to a case where, instead of the edge ring FR, the thickness of another consumable member (for example, a cover ring, a top plate of an upper electrode, or the like) attached in the process module PM is detected.

In the embodiments described above, the thickness detection sensor S11 that detects the thickness of the consumable member is disposed outside the chamber in the plasma processing systems PS1 to PS5. However, the present disclosure is not limited thereto. For example, instead of the thickness detection sensor S11, a state detection sensor that detects the state of the consumable member, such as the surface state of the consumable member, may be disposed.

Further, when the state of the consumable member is detected by the state detection sensor, detecting the state of the consumable member in an area (straight line or surface) instead of a spot (one point) enables to detect a shape (inclination, irregularity, distortion, deflection, warp, or the like) of the consumable member. As an example, the state of the edge ring FR at a plurality of points (or lines) can be detected by rotating the edge ring FR. Further, by using a sensor such as a line sensor, the state of the edge ring FR at a plurality of points (or lines) can be detected. Further, these materials may be combined. As a result, it is possible to detect shapes such as inclination, irregularities, distortion, deflection, and warpage over the entire periphery of the edge ring FR.

1. A plasma processing system for performing plasma processing on a substrate, the plasma processing system comprising:
a chamber to which a consumable member is attached inside;
a vacuum transfer chamber connected to the chamber;
a transfer device provided in the vacuum transfer chamber and configured to transfer the consumable member between the chamber and the transfer device;
a measuring instrument provided outside the chamber in the plasma processing system and configured to detect a state of the consumable member, and
a controller configured to control each element of the plasma processing system.

2. The plasma processing system according to claim 1, wherein
the measuring instrument detects the state of the consumable member in a transfer path through which the transfer device transfers the consumable member.

3. The plasma processing system according to claim 1, wherein
the measuring instrument detects the state of the consumable member held by the transfer device.

4. The plasma processing system according to claim 1, wherein
the measuring instrument is provided adjacent to a gate valve provided between the chamber and the vacuum transfer chamber.

5. The plasma processing system according to claim 1, wherein
the measuring instrument is provided at one location of the vacuum transfer chamber.

6. The plasma processing system according to claim 1, wherein
the measuring instrument detects misalignment of the consumable member with respect to a reference position.

7. The plasma processing system according to claim 1, wherein
the measuring instrument detects the state of the consumable member in a non-contact manner.

8. The plasma processing system according to claim 1, wherein
the controller controls the transfer device and the measuring instrument to detect a state of an unused consumable member before the consumable member is loaded into the chamber.

9. The plasma processing system according to claim 1, wherein
the controller controls the transfer device and the measuring instrument to detect a state of the consumable member in use which has subjected to the plasma processing.

10. The plasma processing system according to claim 1, wherein
the controller changes a condition for the plasma processing based on the state of the consumable member detected by the measuring instrument.

11. The plasma processing system of claim 10, wherein
the consumable member is an edge ring disposed around the substrate.

12. The plasma processing system according to claim 11, wherein
the condition for the plasma processing includes a lifting amount of the edge ring.

13. The plasma processing system according to claim 11, wherein
the condition for the plasma processing includes at least one of a supply pressure and a supply flow rate of a heat transfer gas, both being supplied to a rear surface of the edge ring.

14. The plasma processing system according to claim 11, wherein
the condition for the plasma processing includes a magnitude of a bias voltage supplied to the edge ring.

15. The plasma processing system according to claim 11, further comprising:
a heater including a first heater configured to heat a central portion of the substrate and a second heater configured to heat a peripheral portion of the substrate, wherein
the condition for the plasma processing includes a set temperature of the second heater.

16. The plasma processing system according to claim 1, wherein
the state of the consumable member is a thickness of the consumable member.

17. A plasma processing method for performing plasma processing on a substrate, the plasma processing method comprising:
(a) performing plasma processing on the substrate under a first condition in a chamber into which a consumable member is attached;
(b) transferring the consumable member subjected to the plasma processing into a vacuum transfer chamber connected to the chamber;
(c) detecting a state of the consumable member transferred into the vacuum transfer chamber;
(d) transferring the consumable member subjected to the detection of the state into the chamber; and
(e) performing plasma processing on the substrate under a second condition set based on the state of the consumable member in the chamber after (d).

18. The plasma processing method according to claim 17, further comprising: (f) determining whether there is misalignment of the consumable member transferred into the vacuum transfer chamber with respect to a reference position before (c), wherein
(c) is performed when it is determined in (f) that there is no misalignment of the consumable member.

19. The plasma processing method according to claim 18, further comprising: (g) determining whether the misalignment of the consumable member is correctable or not when it is determined in (f) that there is the misalignment of the consumable member, wherein
(c) is performed when it is determined in (g) that the misalignment is correctable.

20. The plasma processing method according to claim 17, further comprising: (h) cleaning an inside of the chamber after (b) and before (d).

21. The plasma processing method according to claim 17, further comprising: (i) determining whether the state of the consumable member detected in (c) is within an allowable range or not after (c) wherein (d) is performed when it is determined in (i) that the state of the consumable member is within the allowable range.

22. The plasma processing method according to claim 17, wherein
the state of the consumable member represents a thickness of the consumable member.
